(19) United States
(12) Patent Application Publication
(10) Pub. No.: US 2015/0228807 A1
(43) Pub. Date: Aug. 13, 2015

(54) VERTICAL PIN DIODE

(71) Applicant: Electronics & Telecommunications Research Institute, Daejeon (KR)

(72) Inventors: Cheol Ho KIM, Gunpo-si (KR); Kwang Chun LEE, Daejeon (KR)

(73) Assignee: Electronics & Telecommunications Research Institute, Daejeon (KR)

(21) Appl. No.: 14/619,666

(22) Filed: Feb. 11, 2015

(30) Foreign Application Priority Data
Feb. 12, 2014 (KR) 10-2014-0016296

(51) Int. Cl. H01L 29/868; H01L 29/417

(52) U.S. Cl. CPC H01L 29/868; H01L 29/417

(57) ABSTRACT

Disclosed is a vertical positive-intrinsic-negative (PIN) diode. The vertical PIN diode includes an intrinsic layer, an N-type layer located on a first surface of the intrinsic layer, a P-type layer located on a second surface of the intrinsic layer, wherein the second surface is opposite to the first surface, a connection layer formed to extend to the first surface from the P-type layer, a first electrode located on the N-type layer, and a second electrode located in the connection area formed on the first surface. Thus, plasma can be easily generated.

### CLAIM FOR PRIORITY

This application claims priority to Korean Patent Application No. 2014-0016296 filed on Feb. 12, 2014 in the Korean Intellectual Property Office (KIPO), the entire contents of which are hereby incorporated by reference.

### BACKGROUND

1. Technical Field

Example embodiments of the present invention relate to a vertical positive-intrinsic-negative (PIN) diode, and more particularly, to a vertical PIN diode used for activating solid plasma.

2. Related Art

Solid plasma antennas refer to antennas which transmit signals using variability of a semiconductor substrate (from a dielectric to a conductor). That is, an electrical or optical impact is applied to a specific area of the semiconductor substrate, the specific area is changed to a conductor state, i.e., in a plasma state, and signals are transmitted through the area which has been changed to the conductor state. When such characteristics are used, a beam direction and a frequency bandwidth of an antenna can be easily controlled.

In the solid plasma antenna, horizontal positive-intrinsic-negative (PIN) diodes or vertical PIN diodes are used to activate plasma. In the case of conventional horizontal PIN diodes, a high voltage should be applied to generate sufficient free electrons due to a high loss of current in a surface of a Si layer. Meanwhile, in the conventional vertical PIN diodes, since electrodes are respectively located on both surfaces of a substrate, i.e., an upper surface and a lower surface, signal processing can be impeded in antenna applications.

### SUMMARY

Accordingly, example embodiments of the present invention are provided to substantially obviate one or more problems due to limitations and disadvantages of the related art.

Example embodiments of the present invention provide a vertical positive-intrinsic-negative (PIN) diode for configuring electrodes of a diode to be located on the same surface.

In some example embodiments, a vertical PIN diode includes an intrinsic layer, an N-type layer located on a first surface of the intrinsic layer, a P-type layer located on a second surface of the intrinsic layer, wherein the second surface is opposite to the first surface, a connection area formed to extend to the first surface from the P-type layer, a first electrode located on the N-type layer, and a second electrode located in the connection area formed on the first surface.

Here, the vertical PIN diode may further include a first oxide layer located on the first surface for the intrinsic layer and the N-type layer

Here, the vertical PIN diode may further include a second oxide layer located on the second surface for the intrinsic layer and the P-type layer.

Here, the first electrode and the second electrode may be located on surfaces formed in the same direction.

Here, the connection area may be formed of a conductive material.

Here, the connection area may be formed in a trench shape.

Here, a surface of the connection area abutting the P-type layer may have a size smaller than a surface abutting the first surface.

In other example embodiments, a vertical PIN diode includes an intrinsic layer, a P-type layer located on a first surface of the intrinsic layer, an N-type layer located on a second surface of the intrinsic layer, wherein the second surface is opposite to the first surface, a connection area formed to extend to the first surface from the N-type layer, a first electrode located on the P-type layer, and a second electrode located in the connection area formed on the first surface.

Here, the vertical PIN diode may further include a first oxide layer located on the first surface of the intrinsic layer and the P-type layer.

Here, the vertical PIN diode may further include a second oxide layer located on the second surface of the intrinsic layer and the N-type layer.

Here, the first electrode and the second electrode may be located on a surface formed in the same direction.

Here, the connection area may be formed of a conductive material.

Here, the connection area may be formed in a trench shape.

Here, a surface of the connection area abutting the N-type layer may have a size smaller than a surface abutting the first surface.

### BRIEF DESCRIPTION OF DRAWINGS

Example embodiments of the present invention will become more apparent by describing in detail example embodiments of the present invention with reference to the accompanying drawings, in which:

FIG. 1 is a perspective view illustrating a horizontal positive-intrinsic-negative (PIN) diode;

FIG. 2 is a cross-sectional view illustrating a vertical PIN diode according to an embodiment of the present invention;

FIG. 3 is a projection view illustrating the vertical PIN diode according to the embodiment of the present invention;

FIG. 4 is a cross-sectional view illustrating a vertical PIN diode according to another embodiment of the present invention; and

FIG. 5 is a cross-sectional view illustrating a vertical PIN diode according to still another embodiment of the present invention.

### DESCRIPTION OF EXAMPLE EMBODIMENTS

Example embodiments of the present invention are disclosed herein. However, specific structural and functional details disclosed herein are merely representative for purposes of describing example embodiments of the present invention.

However, example embodiments of the present invention may be embodied in many alternate forms and should not be construed as limited to example embodiments of the to present invention set forth herein and example embodiments of the present invention are to cover all modifications, equivalents, and alternatives falling within the spirit and scope of the invention.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be described in detail below with reference to the accompanying drawings. While the present invention is shown and described in connection with exemplary embodiments thereof, same or similar elements regardless of reference numerals refer to same reference numerals, and redundant descriptions thereof will be omitted.

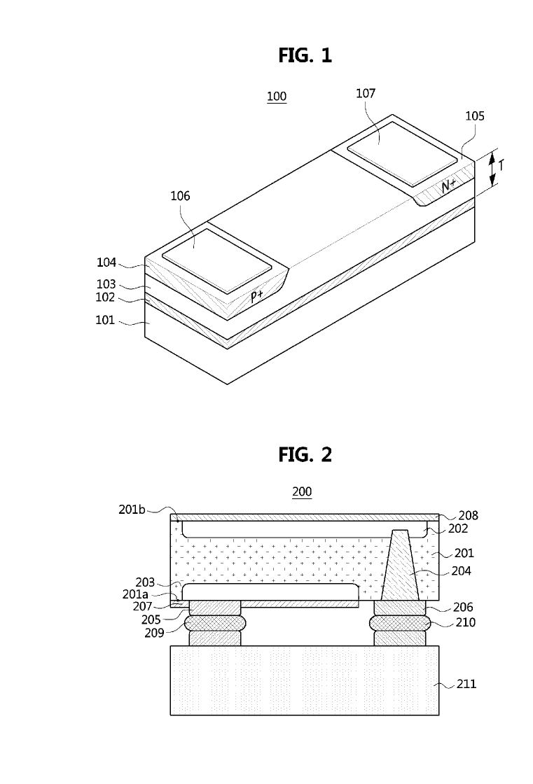

FIG. 1 is a perspective view illustrating a horizontal PIN diode.

Referring to FIG. 1, a horizontal positive-intrinsic-negative (PIN) diode 100 may include a Si substrate 101, an oxide layer 102, an intrinsic layer 103, a P-type layer 104, an N-type layer 105, a P-electrode 106, and an N-electrode 107.

The oxide layer 102 may be located on an upper surface of the Si substrate 101 and the intrinsic layer 103 may be located on an upper surface of the oxide layer 102. The P-type layer 104 may be partly formed on an upper surface of the intrinsic layer 103 and the N-type layer 105 may be formed on a remaining upper surface of the intrinsic layer 103 on which the P-type layer 104 is not formed. For example, the P-type layer 104 may be formed to be opposite the N-type layer 105 on the upper surface of the intrinsic layer 103. The P-electrode 106 may be located on an upper surface of the P-type layer 104 and the N-electrode 107 may be located on an upper surface of the N-type layer 105.

When a forward voltage is applied to the P-electrode 106 and the N-electrode 107, direct current flows in a horizontal direction through the intrinsic layer 103, and thus a horizontal PIN diode may have conductivity by free electrons generated by the direct current.

Such the horizontal PIN diode has a simple structure in which both two electrodes are located on the same surface, thereby being easily applied to an antenna. However, since current mainly flows through the intrinsic layer 103 in the horizontal pin diode 100, a loss of the current is high in the upper surface of the intrinsic layer 103, and a moving path of the current is long, a high voltage should be applied to generate sufficient free electrons. Further, a current flow in a constant direction should be formed in series in SPIN arrangement and a higher voltage should be applied according to an increase in the number of arrangements.

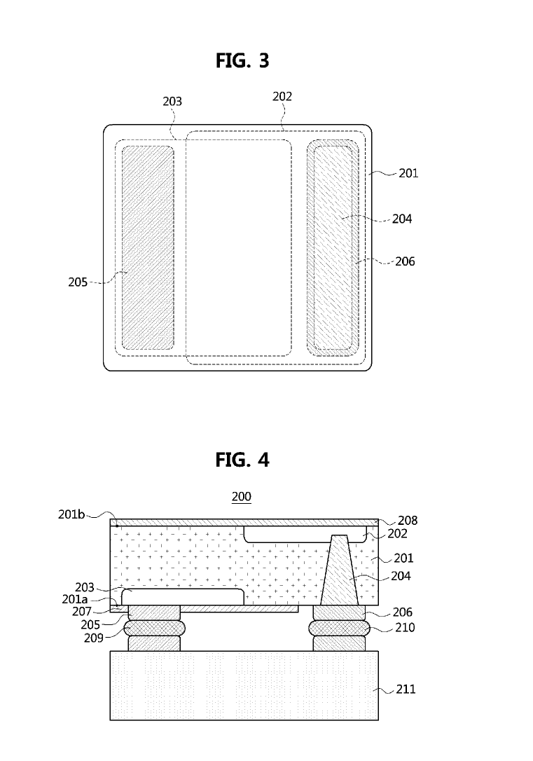

FIG. 2 is a cross-sectional view illustrating a vertical PIN diode according to an embodiment of the present invention, and FIG. 3 is a projection view illustrating the vertical PIN diode according to the embodiment of the present invention.

Referring to FIGS. 2 and 3, a vertical PIN diode 200 may include an intrinsic layer 201, an N-type layer 203 formed in a lower area of the intrinsic layer 201, a P-type layer 202 formed in an upper area of the intrinsic layer 201, a connection area 204 formed to extend to the lower area of the intrinsic layer 201 from the P-type layer 202, a first electrode 205 located under the N-type layer 203, and a second electrode 206 located under the connection area 204.

Furthermore, the vertical PIN diode 200 may further include a first oxide layer 207 located under the intrinsic layer 201 and the N-type layer 203, a second oxide layer 208 on the intrinsic layer 201 and the P-type layer 202, a first bump 209 located under the first electrode 205, and a second bump 210 located under the second electrode 206, and a connection layer 211 connecting the first electrode 205 and the second electrode 206.

A fundamental configuration of the vertical PIN diode 200 includes the P-type layer 202 located in the upper area of the vertical PIN diode 200, the N-type layer 203 located in the lower area of the vertical PIN diode 200, and the intrinsic layer 201 formed between the P-type layer 202 and the N-type layer 203.

The N-type layer 203 may be formed in the lower area of the intrinsic layer 201, i.e., a first surface 201a, the P-type layer 202 may be formed in the upper area of the intrinsic layer 20, i.e., a second surface 201b. That is, the N-type layer 203 and the P-type layer 202 may be formed on the intrinsic layer 201 to be opposite in a vertical direction. The P-type layer 202 may be formed in an area greater than the N-type layer 203, in an area having the same size as the N-type layer 203, or in an area smaller than the N-type layer 203. Here, the shapes of the P-type layer 202 and the N-type layer 203 formed on the intrinsic layer 201 are not limited to the shapes shown in FIG. 2, but may have various shapes. Meanwhile, the P-type layer 202 may be formed on the lower area of the intrinsic layer 201, i.e., the first surface 201a, and the N-type layer 203 may be formed on the upper area of the intrinsic layer 201, i.e., the second surface 201b.

The connection area 204 may be formed to extend to the lower area of the intrinsic layer 201, i.e., the first surface 201a, from the P-type layer 202. As the connection area 204 is used to apply a voltage to the P-type layer 202, the connection area 204 is connected to only the P-type layer 202 and is not connected to the N-type layer 203. The connection area 204 may be formed of a conductive material such as a metal, etc.

A vertical cross-sectional view of the connection area 204 may have a trapezoidal shape. That is, an upper surface of the connection area 204 abutting the P-type layer 202 may be smaller than a lower surface of the connection area 204 abutting the first surface 201a of the intrinsic layer 201. Otherwise, the upper surface of the connection area 204 abutting the P-type layer 202 may be greater that a lower surface of the connection area 204 abutting the first surface 201a of the intrinsic layer 201. Here, the shape of the connection area 204 is not limited to the shape shown in FIG. 2, but may have various shapes.

The first electrode 205 may be used to apply a voltage to the N-type layer 203. The first electrode 205 may be located on a lower surface of the lower surface of the N-type layer 203, and may have a size smaller than the N-type layer 203. The second electrode 206 may be used to apply a voltage to the P-type layer 202. The second electrode 206 may be located on a lower surface of the connection area 204. Here, the first electrode 205 and the second electrode 206 may be located on a surface formed in the same direction. For example, the first electrode 205 and the second electrode 206 may be formed on the first surface 201a.

The first oxide layer 207 may be located on lower surfaces of the intrinsic layer 201 and the N-type layer 203. That is, the first oxide layer 207 may be formed on the first surface 201a to cover the lower surfaces of the intrinsic layer 201 and the N-type layer 203. The second oxide layer 208 may be located on upper surfaces of the intrinsic layer 201 and the P-type layer 202. That is, the second oxide layer 208 may be formed on the second surface 201b to cover the upper surfaces of the intrinsic layer 201 and the P-type layer 202. Here, the first oxide layer 207 and the second oxide layer 208 are used to compensate for a surface defect generated when electric charges are formed. Meanwhile, the vertical PIN diode 200 may not include at least one of the first oxide layer 207 and the second oxide layer 208.

The first bump 209 may be located on a lower surface the first electrode 205. That is, the first bump 209 is formed between the first electrode 205 and the connection layer 211 to connect the first electrode 205 to the connection layer 211. The second bump 210 may be located on a lower surface of the second electrode 206. That is, the second bump 210 is formed between the second electrode 206 and the connection layer 211 to connect the second electrode 206 to the connection layer 211. The first bump 209 and the second bump 210 may be formed of a conductive material, such as a metal, etc. Meanwhile, the first bump 209 and the second bump 210 may be replaced with another connection method, such as a bonding wire, etc.

The connection layer 211 may be connected to the first electrode 205 through the first bump 209 and to second electrode 206 through the second bump 210. Further, the connection layer 211 may connect at least one between the vertical PIN diodes 200 and may selectively activate a desired vertical PIN diode 200.

In the above-described vertical PIN diode 200, when a forward voltage is applied to the first electrode 205 and the second electrode 206, direct current flows between the P-type layer 202 and the N-type layer 203 in a vertical direction through the intrinsic layer 201. Thus, free electrons are generated in the intrinsic layer 201 by the direct current and the vertical PIN diode 200 may have conductivity.

As the first electrode 205 and the second electrode 206 are located on one surface, the structure of the above-described vertical PIN diode 200 may prevent radio frequency interference due to the electrodes. However, since the P-type layer 202 is widely located on the upper area of the intrinsic layer 201, radio frequency interference may be caused by free charges included in the P-type layer 202 when the vertical PIN diode 200 is in an inactivated state. This problem may be solved by applying a reverse voltage to the vertical PIN diode 200 and moving the free charges included in the P-type layer 202 to the second electrode 206.

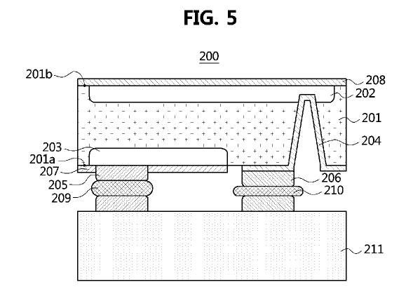

FIG. 4 is a cross-sectional view illustrating a vertical PIN diode according to another embodiment of the present invention.

Referring to FIG. 4, the vertical PIN diode 200 may include an intrinsic layer 201, an N-type layer 203 formed in a lower area of the intrinsic layer 201, a P-type layer 202 formed in an upper area of the intrinsic layer 201, a connection area 204 formed to extend to the lower area of the intrinsic layer 201 from the P-type layer 202, a first electrode 205 located under the N-type layer 203, and a second electrode 206 located under the connection area 204.

Furthermore, the vertical PIN diode 200 may further include a first oxide layer 207 located in lower areas of the intrinsic layer 201 and the N-type layer 203, a second oxide layer 208 located in upper areas of the intrinsic layer 201 and the P-type layer 202, a first bump 209 located under the first electrode 205, a second bump 210 located under the second electrode 206, and a connection layer 211 connecting the first electrode 205 to the second electrode 206.

The fundamental configuration of the vertical PIN diode 200 includes the P-type layer 202 located in the upper area of the vertical PIN diode 200, the N-type layer 203 located in the lower area of the vertical PIN diode 200, and the intrinsic layer 201 formed between the P-type layer 202 and the N-type layer 203. Meanwhile, the P-type layer 202 may be formed in the lower area of the vertical PIN diode 200, and the N-type layer 203 may be formed in the upper area of the vertical PIN diode 200.

Here, the structure of the vertical PIN diode 200 shown in FIG. 4 is equal to that of the vertical PIN diode 200 shown in FIG. 2 except a shape of the P-type layer 202. That is, when the vertical PIN diode 200 is in an inactivated state, the size of the P-type layer 202 may be formed smaller than the P-type layer 202 shown in FIG. 2 to prevent radio frequency interference caused by free charges included in the P-type layer 202.

FIG. 5 is a cross-sectional view illustrating a vertical PIN diode according to still another embodiment of the present invention.

Referring to FIG. 5, a vertical PIN diode 200 may include an intrinsic layer 201, an N-type layer 203 formed in a lower area of the intrinsic layer 201, a P-type layer 202 formed in an upper area of the intrinsic layer 201, a connection area 204 formed to extend to the lower area of the intrinsic layer 201 from the P-type layer 202, a first electrode 205 located under the N-type layer 203, and a second electrode 206 located under the connection area 204.

Furthermore, the vertical PIN diode 200 may further include a first oxide layer 207 located in lower areas of the intrinsic layer 201 and the N-type layer 203, a second oxide layer 208 located in upper areas of the intrinsic layer 201 and the P-type layer 202, a first bump 209 located under the first electrode 205, a second bump 210 located under the second electrode 206, and a connection layer 211 connecting the first electrode 205 to the second electrode 206.

The fundamental configuration of the vertical PIN diode 200 includes the P-type layer 202 located in the upper area of the vertical PIN diode 200, the N-type layer 203 located in the lower area of the vertical pin diode 200, and the intrinsic layer 201 formed between the P-type layer 202 and the N-type layer 203.

Here, the structure of the vertical PIN diode 200 shown in FIG. 5 is equal to that of the vertical PIN diode 200 shown in FIG. 2 except a shape of the connection area 204. That is, the connection area 204 shown in FIG. 5 may be formed in a trench shape unlike the connection area 204 shown in FIG. 2. Similar to this, the connection area 204 of the vertical PIN diode 200 shown in FIG. 4 may be formed in a trench shape.

In the descriptions with reference to the FIGS. 2 to 5, the P-type layer has been described to be located in an upper area of the vertical PIN diode and the N-type layer has been described to be located in a lower area of the vertical PIN diode, but the N-type layer may be located in the upper area of the vertical PIN diode and the P-type layer may be located in the lower area the vertical PIN diode.

That is, the vertical PIN diode may include an intrinsic layer, an N-type layer formed in an upper area of the intrinsic layer, a P-type layer formed in a lower area of the intrinsic layer, a connection area formed to extend to the lower area of the intrinsic layer from the N-type layer, a first electrode located on the P-type layer, and a second electrode located in the connection area. Furthermore, the vertical PIN diode may further include a first oxide layer located in lower areas of the intrinsic layer and the P-type layer, a second oxide layer located in upper areas of the intrinsic layer and the N-type layer, a first bump located under the first electrode, a second bump located under the second electrode, and a connection layer connecting the first electrode to the second electrode.

The fundamental configuration of the vertical PIN diode includes the N-type layer located in the upper area of the vertical PIN diode, the P-type layer located in the lower area of the vertical PIN diode, and the intrinsic layer formed between the N-type layer and the P-type layer.

The above described vertical PIN diode is equal to the vertical PIN diode shown in FIGS. 2 to 5 except that the N-type layer is located on the upper surface of the intrinsic layer and the P-type layer is located on the lower surface of the intrinsic layer.

That is, the N-type layer located in the upper area of the vertical PIN diode may be formed to be located in most areas of the upper surface of the vertical PIN diode such as the P-type layer shown in FIGS. 2 and 3, or may be formed to be located in a part of the upper surface of the vertical PIN diode such as the P-type layer shown in FIG. 4. Further, the connection area of the vertical PIN diode may have the same shape as the connection area shown in FIGS. 2 to 4, or be formed in a trench shape such as the connection area shown in FIG. 5.

In the above described vertical PIN diode, when a forward voltage is applied to the first electrode and the second electrode, direct current may flow in a vertical direction between the P-type layer and the N-type layer through the intrinsic layer. Free electrons are generated in the intrinsic layer due to the direct current, and thus the vertical PIN diode may have conductivity.

According to example embodiments of the present invention, as the vertical PIN diode is used, a relatively larger amount of charges are generated even using a small voltage, and thus plasma can be easily generated.

Further, as the vertical PIN diode including electrodes located on the same surface is used, radio frequency interference can be minimized.

While the example embodiments of the present invention and their advantages have been described in detail, it should be understood that various changes, substitutions and alterations may be made herein without departing from the scope of the invention.

What is claimed is:

1. A vertical positive-intrinsic-negative (PIN) diode comprising:
an intrinsic layer;
an N-type layer located on a first surface of the intrinsic layer;
a P-type layer located on a second surface of the intrinsic layer, wherein the second surface is opposite to the first surface;
a connection layer formed to extend to the first surface from the P-type layer;
a first electrode located on the N-type layer; and
a second electrode located in the connection area formed on the first surface.

2. The vertical pin diode of claim 1, further comprising a first oxide layer located on the first surface of the intrinsic layer and the N-type layer.

3. The vertical pin diode of claim 1, further comprising a second oxide layer located on the second surface of the intrinsic layer and the P-type layer.

4. The vertical pin diode of claim 1, wherein the first electrode and the second electrode are located on a surface formed in the same direction.

5. The vertical pin diode of claim 1, wherein the connection area is formed of a conductive material.

6. The vertical pin diode of claim 1, wherein the connection area is formed in a trench shape.

7. The vertical pin diode of claim 1, wherein a surface of the connection area abutting the P-type layer has a size smaller than a surface abutting the first surface.

8. A vertical PIN diode comprising:
an intrinsic layer;
a P-type layer located on a first surface of the intrinsic layer;
an N-type layer located on a second surface of the intrinsic layer, wherein the second surface is opposite to the first surface;
a connection area formed to extend to the first surface from the N-type layer;
a first electrode located on the P-type layer; and
a second electrode located in the connection area formed on the first surface.

9. The vertical pin diode of claim 8, further comprising a first oxide layer located on the first surface for the intrinsic layer and the P-type layer.

10. The vertical pin diode of claim 8, further comprising a second oxide layer located on the second surface for the intrinsic layer and the N-type layer.

11. The vertical pin diode of claim 8, wherein the first electrode and the second electrode are located on a surface formed in the same direction.

12. The vertical pin diode of claim 8, wherein the connection area is formed of a conductive material.

13. The vertical pin diode of claim 8, wherein the connection area is formed in a trench shape.

14. The vertical pin diode of claim 8, wherein a surface of the connection area abutting the N-type layer has a size smaller than a surface abutting the first surface.
